(19) United States
(12) Patent Application Publication
(10) Pub. No.: US 2025/0231499 A1
(43) Pub. Date: Jul. 17, 2025

(54) METHOD AND APPARATUS FOR ILLUMINATION ADJUSTMENT

(71) Applicant: ASML NETHERLANDS B.V., Veldhoven (NL)

(72) Inventors: Changsik YOON, Waalre (NL); Armand Eugene Albert KOOLEN, Nuth (NL); Jasper Niko Maria HOOGVELD, Tilburg (NL); Sjoerd Arthur HACK, Veldhoven (NL)

(73) Assignee: ASML NETHERLANDS B.V., Veldhoven (NL)

(21) Appl. No.: 18/728,004

(22) PCT Filed: Dec. 30, 2022
(86) PCT No.: PCT/EP2022/088095

§ 371 Date: Jul. 10, 2024

Related U.S. Application Data
(60) Provisional application No. 63/302,214, filed on Jan. 24, 2022.

(51) Int. Cl. G03F 7/00; G03F 9/00

(52) U.S. Cl. CPC G03F 7/706849; G03F 7/706; G03F 7/70633; G03F 9/7026

(57) ABSTRACT

Systems and methods provide the ability to mitigate linear and/or offset coma present in an objective of a metrology tool. A method of reducing an effect of offset coma in a metrology apparatus includes rotating an objective lens element of the metrology apparatus until a best contrast for physically separated first and second portions of a metrology target is determined. A method of reducing an effect of linear coma in a metrology apparatus includes determining an amount of an axially symmetric coma aberration present in a lens system of the metrology device, and moving an optical element of the lens system in an axial z-direction to reduce the determined axially symmetric coma. A lens stop or other lens element may be moved in the z-direction to reduce coma. The two approaches may be combined.

### CROSS-REFERENCE TO RELATED APPLICATIONS

This application claims priority of U.S. application 63/302,214 which was filed on Jan. 24, 2022 and which is incorporated herein in its entirety by reference.

### FIELD

The present disclosure relates generally to metrology methods and tools for use in lithographic apparatuses and more particularly to methods and systems allowing for mitigation of linear and/or offset coma present in an objective lens of an inspection tool.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g., including part of, one, or several dies) on a substrate (e.g., a silicon wafer). Transfer of the pattern is typically via imaging onto a layer of radiation-sensitive material (resist) provided on the substrate. In general, a single substrate will contain a network of adjacent target portions that are successively patterned. Known lithographic apparatus include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the substrate parallel or anti parallel to this direction. It is also possible to transfer the pattern from the patterning device to the substrate by imprinting the pattern onto the substrate.

### SUMMARY

In order to allow a number of patterned layers to be positioned on a substrate, it is desirable to accurately set the position of the substrate relative to the radiation beam and the patterning device. This may be performed by accurately positioning the substrate on a substrate table and positioning the substrate table relative to the radiation beam and the patterning device.

Alignment of the substrate may be performed. In one alignment system, a number of alignment marks on the substrate are measured to derive a coordinate system, which is compared to a modelled grid to derive the positions of features on the substrate. Clamping of the substrate on the substrate table, or wafer distortion occurring in non-lithography process steps, may cause distortion of the substrate, which can be monitored by comparison of the measurements to the grid. Models describing the wafer grid may be created which are used in exposing wafers so as to compensate for the distortions.

One property of particular interest is overlay, i.e., the alignment of successive layers formed on the substrate. Measurements of overlay may be made using a modelled grid as described above. Grid models describing the overlay error over the substrate with respect to the previous layer may be produced and used in a control loop to ensure lot to lot consistency.

In order to provide a useful model for substrate properties across the substrate, a number of positions at which measurements may be made may be required. Accordingly, when a layout of a substrate, namely the arrangement of patterns to be formed on the substrate, is planned, a number of sample positions are provided. The requisite substrate property may be measured at each sample position or derived from measurements made at each sample position.

The present description relates to methods and apparatus for using patterning device induced phase in, for example, optimization of the patterning device pattern and one or more properties of illumination of the patterning device, in design of the one or more structural layers on the patterning device, and/or in computational lithography.

In an aspect, there is a method of reducing an effect of offset coma in a metrology apparatus wherein for a diffraction based overlay target having first and second portions separate from each other, a best contrast for the first portion is obtained at a first substrate z-position, and a best contrast for the second portion is obtained at a second substrate z-position, different from the first substrate z-position, the method comprising, the method including rotating an objective lens element of the metrology apparatus until a best contrast for the first and second portions is achieved at a single substrate z-position, different from the first and second substrate z-positions.

In an aspect, a method of reducing an effect of linear coma in a metrology apparatus includes determining an amount of an axially symmetric coma aberration present in a lens system of the metrology device, and moving an optical element of the lens system in an axial z-direction to reduce the determined axially symmetric coma.

In an aspect, a metrology apparatus is configured to reduce an effect of coma and includes an imaging lens system, configured and arranged to image microscopic diffractive patterns on a substrate, and at least one actuator, disposed within the imaging lens system, and configured and arranged to move at least one optical element of the imaging lens system to reduce the effect of offset and/or linear coma in the imaging lens system.

In an aspect, there is provided a method of manufacturing devices wherein a device pattern is applied to a series of substrates using a lithographic process, the method including preparing the device pattern using a method described herein and exposing the device pattern onto the substrates.

In an aspect, there is provided a non-transitory computer program product comprising machine-readable instructions configured to cause a processor to cause performance of a method described herein.

In an aspect, there is provided a method of manufacturing devices wherein a device pattern is applied to a series of substrates using a lithographic process, the method including adapting the design for the patterning device using the method described herein.

### BRIEF DESCRIPTION OF THE DRAWINGS

Embodiments will now be described, by way of example only, with reference to the accompanying drawings in which:

FIG. 1 schematically depicts an embodiment of a lithographic apparatus;

FIG. 2 schematically depicts an embodiment of a lithographic cell or cluster;

FIG. 3 schematically depicts an embodiment of a scatterometer for use as a metrology device;

FIG. 4 schematically depicts another embodiment of a scatterometer for use as a metrology device;

FIG. 5 depicts a composite metrology target formed on a substrate;

FIGS. 6a-f are images showing contrast and best focus conditions for each of a normal and complementary image from a metrology mark;

FIGS. 7a-c are contrast vs z-position for a theoretical substrate under inspection, illustrating focus offset for different rotations of an objective; and

FIG. 8 is a schematic illustration of a system for control of a position of an element of the objective to correct for linear coma.

### DETAILED DESCRIPTION

Before describing embodiments in detail, it is instructive to present an example environment in which embodiments may be implemented.

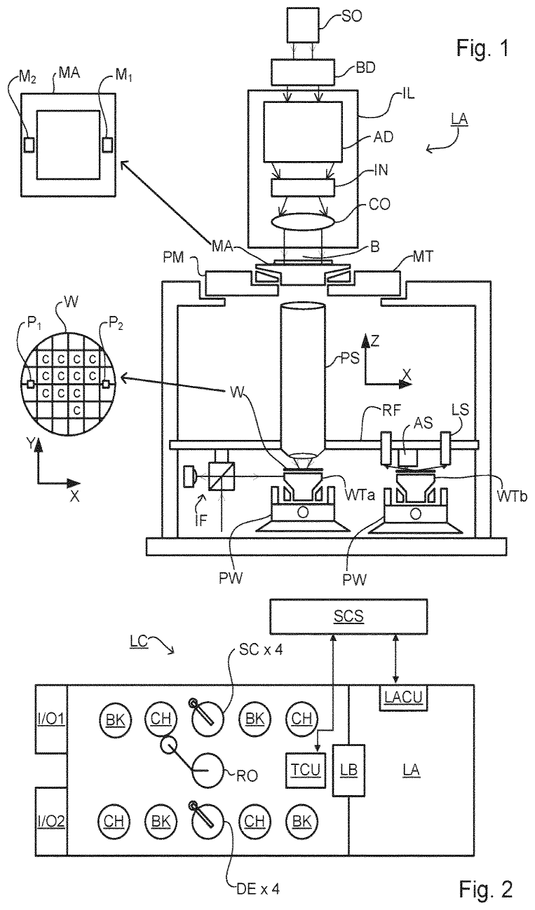

FIG. 1 schematically depicts a lithographic apparatus LA. The apparatus comprises:
an illumination system (illuminator) IL configured to condition a radiation beam B (e.g. DUV radiation or EUV radiation);
a support structure (e.g. a mask table) MT constructed to support a patterning device (e.g. a mask) MA and connected to a first positioner PM configured to accurately position the patterning device in accordance with certain parameters;
a substrate table (e.g. a wafer table) WTa constructed to hold a substrate (e.g. a resist-coated wafer) W and connected to a second positioner PW configured to accurately position the substrate in accordance with certain parameters; and
a projection system (e.g. a refractive projection lens system) PS configured to project a pattern imparted to the radiation beam B by patterning device MA onto a target portion C (e.g. comprising one or more dies) of the substrate W.

The illumination system may include various types of optical components, such as refractive, reflective, magnetic, electromagnetic, electrostatic or other types of optical components, or any combination thereof, for directing, shaping, or controlling radiation.

The patterning device support structure holds the patterning device in a manner that depends on the orientation of the patterning device, the design of the lithographic apparatus, and other conditions, such as for example whether or not the patterning device is held in a vacuum environment. The patterning device support structure can use mechanical, vacuum, electrostatic or other clamping techniques to hold the patterning device. The patterning device support structure may be a frame or a table, for example, which may be fixed or movable as required. The patterning device support structure may ensure that the patterning device is at a desired position, for example with respect to the projection system. Any use of the terms “reticle” or “mask” herein may be considered synonymous with the more general term “patterning device.”

The term “patterning device” used herein should be broadly interpreted as referring to any device that can be used to impart a radiation beam with a pattern in its cross-section such as to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in the target portion, such as an integrated circuit.

The patterning device may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions. The tilted mirrors impart a pattern in a radiation beam, which is reflected by the mirror matrix.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system”.

As here depicted, the apparatus is of a transmissive type (e.g., employing a transmissive mask). Alternatively, the apparatus may be of a reflective type (e.g., employing a programmable mirror array of a type as referred to above, or employing a reflective mask).

The lithographic apparatus may be of a type having two (dual stage) or more tables (e.g., two or more substrate table, two or more patterning device support structures, or a substrate table and metrology table). In such “multiple stage” machines the additional tables may be used in parallel, or preparatory steps may be carried out on one or more tables while one or more other tables are being used for exposure.

The lithographic apparatus may also be of a type wherein at least a portion of the substrate may be covered by a liquid having a relatively high refractive index, e.g., water, so as to fill a space between the projection system and the substrate. An immersion liquid may also be applied to other spaces in the lithographic apparatus, for example, between the mask and the projection system. Immersion techniques are well known in the art for increasing the numerical aperture of projection systems. The term “immersion” as used herein does not mean that a structure, such as a substrate, must be submerged in liquid, but rather only means that liquid is located between the projection system and the substrate during exposure.

Referring to FIG. 1, the illuminator IL receives a radiation beam from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD including, for example, suitable directing mirrors and/or a beam expander. In other cases the source may be an integral part of the lithographic apparatus, for example when the source is a mercury lamp. The source SO and the illuminator IL, together with the beam delivery system BD if required, may be referred to as a radiation system.

The illuminator IL may include an adjuster AD for adjusting the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may include various other components, such as an integrator IN and a condenser CO. The illuminator may be used to condition the radiation beam, to have a desired uniformity and intensity distribution in its cross section.

The radiation beam B is incident on the patterning device (e.g., mask) MA, which is held on the patterning device support (e.g., mask table MT), and is patterned by the patterning device. Having traversed the patterning device (e.g., mask) MA, the radiation beam B passes through the projection system PS, which focuses the beam onto a target portion C of the substrate W. With the aid of the second positioner PW and position sensor IF (e.g., an interferometric device, linear encoder, 2-D encoder or capacitive sensor), the substrate table WTa can be moved accurately, e.g., so as to position different target portions C in the path of the radiation beam B. Similarly, the first positioner PM and another position sensor (which is not explicitly depicted in FIG. 1) can be used to accurately position the patterning device (e.g., mask) MA with respect to the path of the radiation beam B, e.g., after mechanical retrieval from a mask library, or during a scan. In general, movement of the patterning device support (e.g., mask table) MT may be realized with the aid of a long-stroke module (coarse positioning) and a short-stroke module (fine positioning), which form part of the first positioner PM. Similarly, movement of the substrate table WTa may be realized using a long-stroke module and a short-stroke module, which form part of the second positioner PW. In the case of a stepper (as opposed to a scanner) the patterning device support (e.g., mask table) MT may be connected to a short-stroke actuator only, or may be fixed.

Patterning device (e.g., mask) MA and substrate W may be aligned using mask alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the patterning device (e.g., mask) MA, the mask alignment marks may be located between the dies. Small alignment markers may also be included within dies, in amongst the device features, in which case it is desirable that the markers be as small as possible and not require any different imaging or process conditions than adjacent features. The alignment system, which detects the alignment markers is described further below.

The depicted apparatus could be used in at least one of the following modes:
In step mode, the patterning device support (e.g., mask table) MT and the substrate table WTa are kept essentially stationary, while an entire pattern imparted to the radiation beam is projected onto a target portion C at one time (i.e., a single static exposure). The substrate table WTa is then shifted in the X and/or Y direction so that a different target portion C can be exposed. In step mode, the maximum size of the exposure field limits the size of the target portion C imaged in a single static exposure.
In scan mode, the patterning device support (e.g., mask table) MT and the substrate table WTa are scanned synchronously while a pattern imparted to the radiation beam is projected onto a target portion C (i.e., a single dynamic exposure). The velocity and direction of the substrate table WTa relative to the patterning device support (e.g., mask table) MT may be determined by the (de-)magnification and image reversal characteristics of the projection system PS. In scan mode, the maximum size of the exposure field limits the width (in the non-scanning direction) of the target portion in a single dynamic exposure, whereas the length of the scanning motion determines the height (in the scanning direction) of the target portion.
In another mode, the patterning device support (e.g., mask table) MT is kept essentially stationary holding a programmable patterning device, and the substrate table WTa is moved or scanned while a pattern imparted to the radiation beam is projected onto a target portion C. In this mode, generally a pulsed radiation source is employed and the programmable patterning device is updated as required after each movement of the substrate table WTa or in between successive radiation pulses during a scan. This mode of operation can be readily applied to maskless lithography that utilizes programmable patterning device, such as a programmable mirror array of a type as referred to above.

Combinations and/or variations on the above described modes of use or entirely different modes of use may also be employed.

Lithographic apparatus LA is of a so-called dual stage type which has two tables WTa, WTb (e.g., two substrate tables) and two stations—an exposure station and a measurement station—between which the tables can be exchanged. For example, while a substrate on one table is being exposed at the exposure station, another substrate can be loaded onto the other substrate table at the measurement station and various preparatory steps carried out. The preparatory steps may include mapping the surface control of the substrate using a level sensor LS and measuring the position of alignment markers on the substrate using an alignment sensor AS, both sensors being supported by a reference frame RF. If the position sensor IF is not capable of measuring the position of a table while it is at the measurement station as well as at the exposure station, a second position sensor may be provided to enable the positions of the table to be tracked at both stations. As another example, while a substrate on one table is being exposed at the exposure station, another table without a substrate waits at the measurement station (where optionally measurement activity may occur). This other table has one or more measurement devices and may optionally have other tools (e.g., cleaning apparatus). When the substrate has completed exposure, the table without a substrate moves to the exposure station to perform, e.g., measurements and the table with the substrate moves to a location (e.g., the measurement station) where the substrate is unloaded and another substrate is load. These multi-table arrangements enable a substantial increase in the throughput of the apparatus.

As shown in FIG. 2, the lithographic apparatus LA may form part of a lithographic cell LC, also sometimes referred to as a lithocell or lithocluster, which also includes apparatus to perform one or more pre- and post-exposure processes on a substrate. Conventionally these include one or more spin coaters SC to deposit a resist layer, one or more developers DE to develop exposed resist, one or more chill plates CH and one or more bake plates BK. A substrate handler, or robot, RO picks up a substrate from input/output ports I/O1, I/O2, moves it between the different process devices and delivers it to the loading bay LB of the lithographic apparatus. These devices, which are often collectively referred to as the track, are under the control of a track control unit TCU which is itself controlled by the supervisory control system SCS, which also controls the lithographic apparatus via lithographic control unit LACU. Thus, the different apparatus may be operated to maximize throughput and processing efficiency.

In order that the substrate that is exposed by the lithographic apparatus is exposed correctly and consistently, it is desirable to inspect an exposed substrate to measure one or more properties such as overlay error between subsequent layers, line thickness, critical dimension (CD), etc. If an error is detected, an adjustment may be made to an exposure of one or more subsequent substrates. This may particularly useful, for example, if the inspection can be done soon and fast enough that another substrate of the same batch is still to be exposed. Also, an already exposed substrate may be stripped and reworked (to improve yield) or discarded, thereby avoiding performing an exposure on a substrate that is known to be faulty. In a case where only some target portions of a substrate are faulty, a further exposure may be performed only on those target portions which are good. Another possibility is to adapt a setting of a subsequent process step to compensate for the error, e.g., the time of a trim etch step can be adjusted to compensate for substrate-to-substrate CD variation resulting from the lithographic process step.

In an embodiment, a patterning device MA may be provided with a functional pattern (i.e. a pattern which will form part of an operational device). Alternatively or additionally, the patterning device may be provided with a measurement pattern which does not form part of the functional pattern. The measurement pattern may be, for example, located to one side of the functional pattern. The measurement pattern may be used, for example, to measure alignment of the patterning device relative to the substrate table WT (see FIG. 1) of the lithographic apparatus, or may be used to measure some other parameter (e.g., overlay). The techniques described herein may be applied to such a measurement pattern.

In accordance with various embodiments of the invention, wafer features and lithographic apparatus attributes, either measured or simulated, may be used to update a design for the reticle to improve performance. In one example, locations of metrology targets (measurement patterns) may be located in accordance with measured and/or simulated features of the wafer such that the effects of the wafer features and apparatus attributes are reduced. Alternately, similar features of the wafer and/or lithographic system may be used to update positions and/or orientations for the functional patterns.

By way of introduction, the operation of an inspection apparatus making use of metrology targets is described. An inspection apparatus is used to determine one or more properties of a substrate, and in particular, how one or more properties of different substrates or different layers of the same substrate vary from layer to layer and/or across a substrate. The inspection apparatus may be integrated into the lithographic apparatus LA or the lithocell LC or may be a stand-alone device. To enable most rapid measurements, it is desirable that the inspection apparatus measure one or more properties in the exposed resist layer immediately after the exposure. However, the latent image in the resist has a very low contrast—there is only a very small difference in refractive index between the part of the resist which has been exposed to radiation and that which has not—and not all inspection apparatus have sufficient sensitivity to make useful measurements of the latent image. Therefore measurements may be taken after the post-exposure bake step (PEB) which is customarily the first step carried out on an exposed substrate and increases the contrast between exposed and unexposed parts of the resist. At this stage, the image in the resist may be referred to as semi-latent. It is also possible to make measurements of the developed resist image—at which point either the exposed or unexposed parts of the resist have been removed—or after a pattern transfer step such as etching. The latter possibility limits the possibility for rework of a faulty substrate but may still provide useful information, e.g., for the purpose of process control.

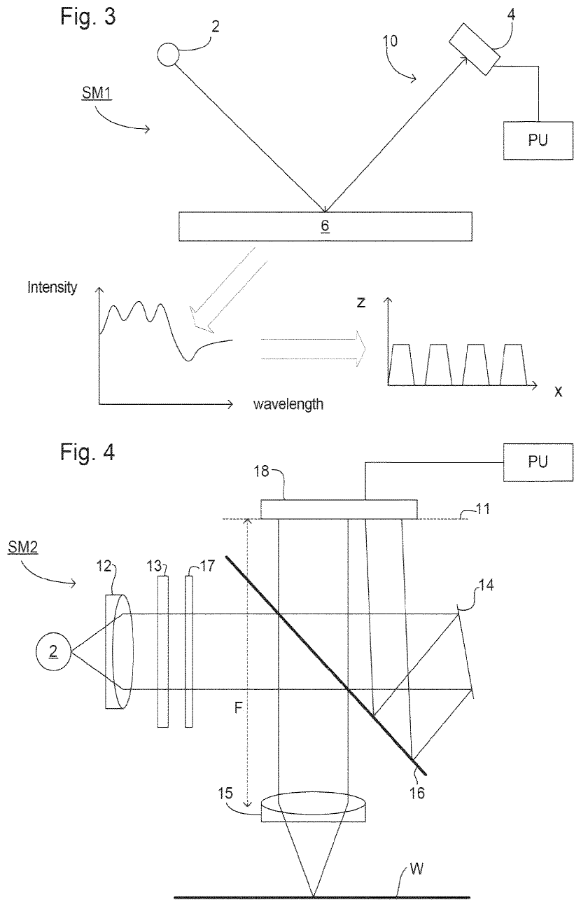

FIG. 3 depicts an embodiment of a scatterometer SM1. It comprises a broadband (white light) radiation projector 2 which projects radiation onto a substrate 6. The reflected radiation is passed to a spectrometer detector 4, which measures a spectrum 10 (i.e., a measurement of intensity as a function of wavelength) of the specular reflected radiation. From this data, the structure or profile giving rise to the detected spectrum may be reconstructed by processing unit PU, e.g., by Rigorous Coupled Wave Analysis and non-linear regression or by comparison with a library of simulated spectra as shown at the bottom of FIG. 3. In general, for the reconstruction, the general form of the structure is known and some parameters are assumed from knowledge of the process by which the structure was made, leaving only a few parameters of the structure to be determined from the scatterometry data. Such a scatterometer may be configured as a normal-incidence scatterometer or an oblique-incidence scatterometer.

Another embodiment of a scatterometer SM2 is shown in FIG. 4. In this device, the radiation emitted by radiation source 2 is focused using lens system 12 through interference filter 13 and polarizer 17, reflected by partially reflective surface 16 and is focused onto substrate W via a microscope objective lens 15, which has a high numerical aperture (NA), desirably at least 0.9 or at least 0.95. An immersion scatterometer may even have a lens with a numerical aperture over 1. The reflected radiation then transmits through partially reflective surface 16 into a detector 18 in order to have the scatter spectrum detected. The detector may be located in the back-projected pupil plane 11, which is at the focal length of the lens 15, however the pupil plane may instead be re-imaged with auxiliary optics (not shown) onto the detector 18. The pupil plane is the plane in which the radial position of radiation defines the angle of incidence and the angular position defines the azimuth angle of the radiation. The detector is desirably a two-dimensional detector so that a two-dimensional angular scatter spectrum (i.e., a measurement of intensity as a function of angle of scatter) of the substrate target can be measured. The detector 18 may be, for example, an array of CCD or CMOS sensors, and may have an integration time of, for example, 40 milliseconds per frame. Non-specular radiation (i.e., diffraction orders of magnitude±1 or higher) may be used in addition to or instead of specular radiation.

A reference beam is often used, for example, to measure the intensity of the incident radiation. To do this, when the radiation beam is incident on the partially reflective surface 16 part of it is transmitted through the surface as a reference beam towards a reference mirror 14. The reference beam is then projected onto a different part of the same detector 18.

One or more interference filters 13 are available to select a wavelength of interest in the range of, say, 405-790 nm or even lower, such as 200-300 nm. The interference filter(s) may be tunable rather than comprising a set of different filters. A grating could be used instead of or in addition to one or more interference filters.

The detector 18 may measure the intensity of scattered radiation at a single wavelength (or narrow wavelength range), the intensity separately at multiple wavelengths or the intensity integrated over a wavelength range. Further, the detector may separately measure the intensity of transverse magnetic- (TM) and transverse electric- (TE) polarized radiation and/or the phase difference between the transverse magnetic- and transverse electric-polarized radiation.

Using a broadband radiation source 2 (i.e., one with a wide range of radiation frequencies or wavelengths—and therefore of colors) is possible, which gives a large etendue, allowing the mixing of multiple wavelengths. The plurality of wavelengths in the broadband desirably each has a bandwidth of δλ and a spacing of at least 2δλ (i.e., twice the wavelength bandwidth). Several “sources” of radiation may be different portions of an extended radiation source which have been split using, e.g., fiber bundles. In this way, angle resolved scatter spectra may be measured at multiple wavelengths in parallel. A 3-D spectrum (wavelength and two different angles) may be measured, which contains more information than a 2-D spectrum. This allows more information to be measured which increases metrology process robustness. This is described in more detail in U.S. Patent Application Publication No. US 2006-0066855, which document is hereby incorporated in its entirety by reference.

By comparing one or more properties of the beam before and after it has been redirected by the target, one or more properties of the substrate may be determined. This may be done, for example, by comparing the redirected beam with theoretical redirected beams calculated using a model of the substrate and searching for the model that gives the best fit between measured and calculated redirected beams. Typically a parameterized generic model is used and the parameters of the model, for example width, height and sidewall angle of the pattern, are varied until the best match is obtained.

Two main types of scatterometer are used. A spectroscopic scatterometer directs a broadband radiation beam onto the substrate and measures the spectrum (intensity as a function of wavelength) of the radiation scattered into a particular narrow angular range. An angularly resolved scatterometer uses a monochromatic radiation beam and measures the intensity (or intensity ratio and phase difference in case of an ellipsometric configuration) of the scattered radiation as a function of angle. Alternatively, measurement signals of different wavelengths may be measured separately and combined at an analysis stage. Polarized radiation may be used to generate more than one spectrum from the same substrate.

In order to determine one or more parameters of the substrate, a best match is typically found between the theoretical spectrum produced from a model of the substrate and the measured spectrum produced by the redirected beam as a function of either wavelength (spectroscopic scatterometer) or angle (angularly resolved scatterometer). To find the best match there are various methods, which may be combined. For example, a first method is an iterative search method, where a first set of model parameters is used to calculate a first spectrum, a comparison being made with the measured spectrum. Then a second set of model parameters is selected, a second spectrum is calculated and a comparison of the second spectrum is made with the measured spectrum. These steps are repeated with the goal of finding the set of parameters that gives the best matching spectrum. Typically, the information from the comparison is used to steer the selection of the subsequent set of parameters. This process is known as an iterative search technique. The model with the set of parameters that gives the best match is considered to be the best description of the measured substrate.

A second method is to make a library of spectra, each spectrum corresponding to a specific set of model parameters. Typically the sets of model parameters are chosen to cover all or almost all possible variations of substrate properties. The measured spectrum is compared to the spectra in the library. Similarly to the iterative search method, the model with the set of parameters corresponding to the spectrum that gives the best match is considered to be the best description of the measured substrate. Interpolation techniques may be used to determine more accurately the best set of parameters in this library search technique.

In any method, sufficient data points (wavelengths and/or angles) in the calculated spectrum should be used in order to enable an accurate match, typically between 80 up to 800 data points or more for each spectrum. Using an iterative method, each iteration for each parameter value would involve calculation at 80 or more data points. This is multiplied by the number of iterations needed to obtain the correct profile parameters. Thus many calculations may be required. In practice this leads to a compromise between accuracy and speed of processing. In the library approach, there is a similar compromise between accuracy and the time required to set up the library.

In any of the scatterometers described above, the target on substrate W may be a grating which is printed such that after development, the bars are formed of solid resist lines. The bars may alternatively be etched into the substrate. The target pattern is chosen to be sensitive to a parameter of interest, such as focus, dose, overlay, chromatic aberration in the lithographic projection apparatus, etc., such that variation in the relevant parameter will manifest as variation in the printed target. For example, the target pattern may be sensitive to chromatic aberration in the lithographic projection apparatus, particularly the projection system PL, and illumination symmetry and the presence of such aberration will manifest itself in a variation in the printed target pattern. Accordingly, the scatterometry data of the printed target pattern is used to reconstruct the target pattern. The parameters of the target pattern, such as line width and shape, may be input to the reconstruction process, performed by a processing unit PU, from knowledge of the printing step and/or other scatterometry processes. Lines in targets may be made up of sub-units, including near or sub-resolution features that together define lines of the gratings, such as are described in U.S. Pat. No. 7,466,413.

While embodiments of a scatterometer have been described herein, other types of metrology apparatus may be used in an embodiment. For example, a dark field metrology apparatus such as described in U.S. Pat. No. 8,797,554, which is incorporated herein in its entirety by reference, may be used. Further, those other types of metrology apparatus may use a completely different technique than scatterometry.

Targets as described herein may be, for example, overlay targets designed for use in the Yieldstar stand-alone or integrated metrology tools, and/or alignment targets such as those typically used with TwinScan lithographic systems, both available from ASML of Veldhoven, NL.

In general, metrology targets for use with such systems should be printed on the wafer with dimensions that meet the design specification for the particular microelectronic device to be imaged on that wafer. As processes continue to push against the limits of lithographic device imaging resolution in advanced process nodes, the design rule and process compatibility requirement place stress on the selection of appropriate targets. As the targets themselves become more advanced, often requiring the use of resolution enhancement technology, such as phase-shift masks, and optical proximity correction, the printability of the target within the process design rules becomes less certain. As a result, proposed marks may be subject to testing in order to confirm their viability, both from a printability and a detectability standpoint. In a commercial environment, good overlay mark detectability may be considered to be a combination of low total measurement uncertainty as well as a short move-acquire-move time, as slow acquisition is detrimental to total throughput for the production line. Modern micro-diffraction-based-overlay targets (μDBO) may be on the order of 10 μm on a side, which provides an inherently lower detection signal compared to 40×160 μm² targets such as those used in the context of monitor wafers.

Additionally, once marks that meet the above criteria have been selected, there is a possibility that detectability will change with respect to process variations, such as film thickness variation, various etch biases, and geometry asymmetries induced by the etch and/or polish processes. Therefore, it may be useful to select a target that has low detectability variation and low overlay/alignment variation against various process variations. Likewise, the fingerprint (printing characteristics, including, for example, lens aberration) of the specific machine that is to be used to produce the microelectronic device to be imaged will, in general, affect the imaging and production of the target marks. It may therefore be useful to ensure that the marks are resistant to fingerprint effects, as some patterns will be more or less affected by a particular lithographic fingerprint.

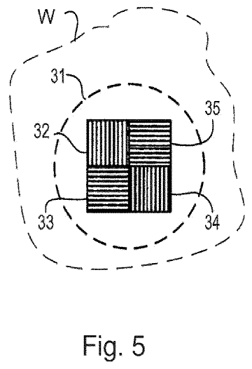

FIG. 5 depicts a composite metrology target formed on a substrate according to known practice. The composite target comprises four gratings 32, 33, 34, 35 positioned closely together so that they will all be within a measurement spot 31 formed by the illumination beam of the metrology apparatus. The four targets thus are all simultaneously illuminated and simultaneously imaged on sensor 4, 18. In an example dedicated to overlay measurement, gratings 32, 33, 34, 35 are themselves composite gratings formed by overlying gratings that are patterned in different layers of the semiconductor device formed on substrate W. Gratings 32, 33, 34, 35 may have differently biased overlay offsets in order to facilitate measurement of overlay between the layers in which the different parts of the composite gratings are formed. Gratings 32, 33, 34, 35 may also differ in their orientation, as shown, so as to diffract incoming radiation in X and Y directions. In one example, gratings 32 and 34 are X-direction gratings with biases of +d, −d, respectively. This means that grating 32 has its overlying components arranged so that if they were both printed exactly at their nominal locations, one of the components would be offset relative to the other by a distance d. Grating 34 has its components arranged so that if perfectly printed there should be an offset of d, but in the opposite direction to the first grating and so on. Gratings 33 and 35 may be Y-direction gratings with offsets +d and −d respectively. While four gratings are illustrated, another embodiment may include a larger matrix to obtain desired accuracy. For example, a 3×3 array of nine composite gratings may have biases −4d, −3d, −2d, −d, 0, +d, +2d, +3d, +4d. Separate images of these gratings can be identified in the image captured by sensor 4, 18.

Measuring focus, overlay and CD on product wafers can be used to determine process errors in producing the product wafers. On the other hand, because marker positions are generally located at positions different from functional structures, and those positions undergo different processing and otherwise have different attributes that affect the ability to ensure that the measurements at marker positions correlate well to actual functional structure attributes. For example, where a target is located in a scribe lane, it may be at a height that differs from a height of a current functional layer of the functional circuit being produced. Likewise, where measurements are distant from critical focus, overlay or critical dimension uniformity constraints, the measurements may not reflect the information that they are intended to.

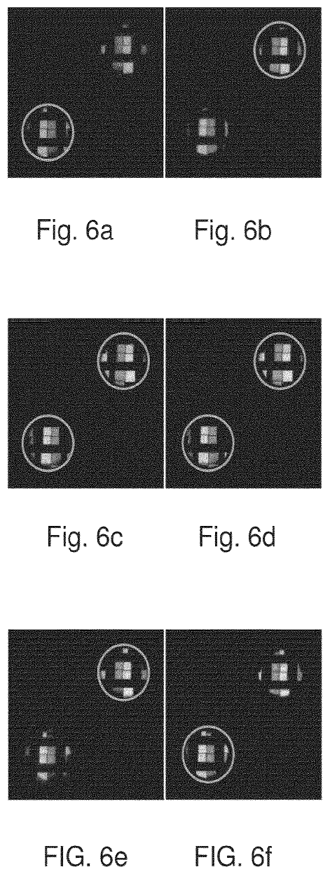

FIG. 6a illustrates a condition in which a first portion of a diffraction grating is in best focus (grey circle). In the illustrated case, this is the normal image and the focal distance is a near distance. That is, the focal plane is relatively near compared to an expected best focus distance, corresponding to a displacement of the best focus plane in the z-direction, nearer to the final element of the objective.

FIG. 6b illustrates a condition in which a second portion is in best focus (grey circle). In this case, this is the complementary image, and the focal distance is a far distance. That is, the focal plane is relatively far compared to an expected best focus distance, corresponding to a displacement of the best focus plane in the z-direction, further from the final element of the objective.

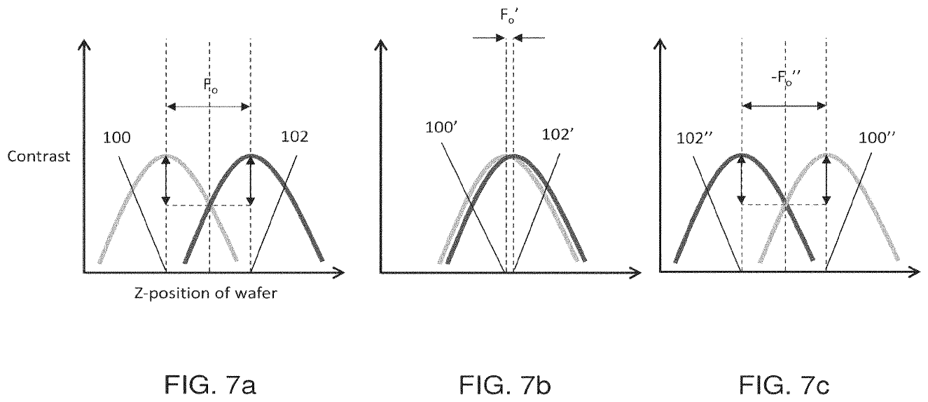

The situation illustrated in FIGS. 6a and 6b is further shown in FIG. 7a. In FIG. 7a, a contrast vs. z-position is shown for each of the two images, and a z-position 100 corresponding to the best focus for the normal image is shown to be nearer than the z-position 102 corresponding to the best focus plane for the complementary image. A difference between the two focal distances F_{O} (focus offset) can be determined.

One possible solution (not shown) is to select an intermediate focus distance at which each of the normal and complementary images is equally, or approximately equally, defocused. However, this is not optimal if the layer being inspected is a critical layer in which the amount of defocus necessary may result in unsatisfactory measurements.

The inventors have determined that a potential cause of this type of focal plane displacement in which normal and complementary images are displaced in different directions is a radially asymmetric distortion such as offset coma. Such offset coma can result from one of the several lens elements of the objective being decentered, for example, or by the objective itself being misaligned with the reference frame of the measurement device. Even if the objective is nearly perfectly assembled, there is the possibility of offset coma being present in the lens design, as all lens systems have some degree of aberration present. A potential solution is to improve objective designs, or to test post-manufacture objectives and select only those that meet heightened criteria, however either of these appears to be impractical in the context of manufacturing as swapping out objectives to find one that is good enough represents a significant waste of resources.

The inventors therefore have determined that it is possible to rotate the objective to mitigate the issue. FIGS. 6c, 6d, and 7b all help to illustrate this solution. FIGS. 6c and 6d each show that for a given rotation, both the normal and complementary images can be obtained in best focus. Similarly, FIG. 7b shows the near overlap of z-position for best focus for each of the normal and complementary images. The focus offset F_{O}′ is considerably smaller. As will be appreciated, this represents a reduction, rather than a complete elimination, of the focus offset. Thus, where considering a best contrast for both of the images, it is understood that there may still remain a reduced degree of focus offset in the system. In various embodiments, the rotation may be selected to remove at least 99%, 95%, 90%, 70%, or 50% of the focus offset, for example, all of which could be considered to be a single position with a best contrast for both positions is obtained.

FIGS. 6e and 6f illustrate the result of continuing to rotate past a selected optimal rotation amount. As is apparent from the figures, and as seen in FIG. 7c, the z-position 100″ of the plane of best focus of the normal image has shifted to a far position relative to the z-position 102″ of the plane of best focus of the complementary image. The focus offset-F_{O}″ is in the opposite direction from that of the original situation depicted in FIGS. 6a, 6b, and 7a.

In an embodiment, the objective is rotated over an interval and a new measurement of best focus is made to determine whether the planes of best focus are within a specified focus offset. For example, each interval may be a selected number of degrees, which could be a fraction of a degree or a few degrees (or radians). In an embodiment, each rotation interval may be as much as 45 degrees. This procedure may be repeated until the desired focus offset, or a minimum focus offset is achieved.

In one embodiment, the adjustment in rotation of the objective is made once, during a manufacturing or set-up operation, and then the objective is solidly mounted into position. In another approach, the adjustment may be performed periodically. In the second approach, an actuator may be included that allows precise rotation to be applied to the objective in response to a control signal changing the setting.

Each imaging process for various layer designs may have a different “fingerprint” resulting in different focus offsets. In this case, an embodiment may allow for further adjusting the rotation when the metrology device is used in conjunction with a different process having a different fingerprint. Differences in the fingerprint over time may result from drift, or from changing process parameters.

For example, the differences may involve different metrology targets, different thicknesses and compositions of stacked layers that introduce variations in the diffracted radiation, and/or targets designed for different critical dimensions that introduce different diffraction effects. In this regard, it is possible to update the rotation by repeating the rotating to change the z-position at which best contrast is achieved based on changes to the fingerprint of the imaging process of the metrology apparatus over time.

In an embodiment, a method of reducing the effects of linear coma is addressed. As will be appreciated, the rotation of the objective described above can address an aberration that is not axially symmetric (such as offset coma), but cannot address axially symmetric aberrations such as linear coma.

Such coma can be a particular problem when the metrology device is operated in a quad aperture or wedge mode. Further, it may be an issue particularly for non-specular modes of operation. This can introduce errors in overlay measurements, which decreases the ability of the metrology device to provide useful information regarding overlay.

As with offset coma, it may be impractical to re-design objectives to reduce the existence of linear coma aberrations. As reduction of such aberrations generally takes the form of increasing a number of lens elements, and often the requirement of using advanced glass materials and complex surfaces, the cost and size of the objective could be greatly increased. Moreover, for a particular lens design, changes in the wafer process under inspection can change the fingerprint, as discussed above. It is not practical to introduce a newly designed objective for each process to be inspected.

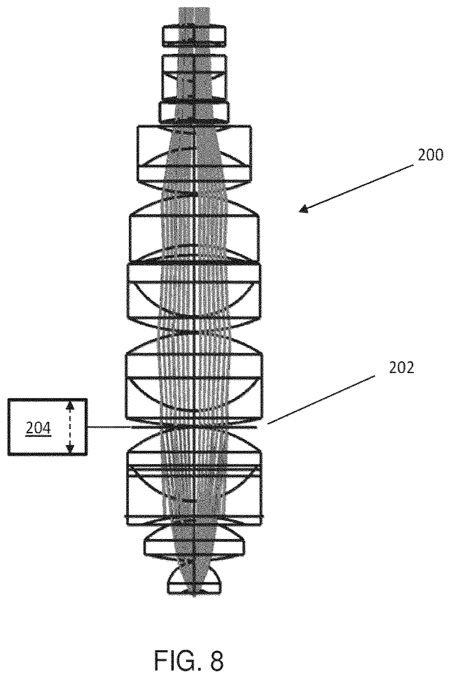

The inventors have determined that one solution to reduce the effects of linear coma in an objective lens 200 (shown in FIG. 8) is to include an aperture stop 202 that can be moved in the z-direction with an actuator 204.

The actuator 204 may be of any suitable type, though as will be understood by the skilled artisan, should be of high precision, introduce minimal contamination or heat, and minimal vibration. The actuator 204 may be composed of one or more individual actuators arranged to move the aperture stop 202 uniformly with one degree of freedom in the z-direction, i.e., without introducing rotations around the x or y axes, to the aperture stop. Such actuators include, for example, linear motors, piezoelectric actuators, and/or shape memory actuators.

The actuator may be a single stage actuator, or may be a fine/coarse actuator combination, such that a first, coarse actuator moves the aperture stop 202 over relatively large distances, for example few millimeters, with lower precision and a second, fine actuator, is responsible for precise positioning over shorter distances, for example, fractions of a millimeter. In general, the movements will be on the order of millimeters.

This movement of the aperture stop 202 produces a pupil defocus change, which in the presence of spherical aberration, leads to a change in linear coma, and an appropriate z-position may be selected for a particular imaging task. Because the amount of linear coma may depend, at least in part, on the metrology target under inspection, it is expected that a change to the z-position may be required on a per job basis, and thus an adjustable actuator, rather than a single calibrated positioning, may provide improved adaptability.

In principle, movement of a pupil within the objective may be obtained without moving an aperture stop. In this approach, a different optical element of the objective lens may be actuatable in the z-direction to achieve the same results. For example, a relay lens, or a relay lens group may be controlled using similar actuator systems to move a position of a pupil within the objective to ameliorate linear coma.

Thus, a general method of reducing coma involves including at least one actuator disposed within the imaging lens system. The actuator is arranged to move at least one optical element of the imaging lens system to reduce the effect of offset and/or linear coma in the imaging lens system. This may take the form of an actuator configured to rotate the objective to reduce offset coma, or an actuator configured to move at least one lens element in the axial z-direction to reduce linear coma.

As will be appreciated, a particular metrology device may experience a combination of linear and offset coma, such that there are mixed causes. In such a situation, a combination of the embodiments may be employed in which both rotation of the objective and z-movement of an element or elements of the objective may be used together to reduce overall effects of coma.

Contrast as discussed herein includes, for an aerial image, image log slope (ILS) and/or normalized image log slope (NILS) and, for resist, dose sensitivity and/or exposure latitude.

The terms “optimize”, “optimizing” and “optimization” as used herein mean adjusting a lithographic process parameter such that results and/or processes of lithography have a more desirable characteristic, such as higher accuracy of projection of a design layout on a substrate, a larger process window, etc.

An embodiment of the invention may take the form of a computer program containing one or more sequences of machine-readable instructions describing a method as disclosed herein, or a data storage medium (e.g. semiconductor memory, magnetic or optical disk) having such a computer program stored therein. Further, the machine readable instruction may be embodied in two or more computer programs. The two or more computer programs may be stored on one or more different memories and/or data storage media.

This computer program may be included, for example, with or within the imaging apparatus of FIG. 1 and/or with or within the control unit LACU of FIG. 2. Where an existing apparatus, for example of the type shown in FIGS. 1 and 2, is already in production and/or in use, an embodiment can be implemented by the provision of updated computer program products for causing a processor of the apparatus to perform a method as described herein.

Any controllers described herein may each or in combination be operable when the one or more computer programs are read by one or more computer processors located within at least one component of the lithographic apparatus. The controllers may each or in combination have any suitable configuration for receiving, processing, and sending signals. One or more processors are configured to communicate with the at least one of the controllers. For example, each controller may include one or more processors for executing the computer programs that include machine-readable instructions for the methods described above. The controllers may include data storage medium for storing such computer programs, and/or hardware to receive such medium. So the controller(s) may operate according the machine readable instructions of one or more computer programs.

The embodiments may further be described using the following clauses:

1. A method of reducing an effect of offset coma in a metrology apparatus wherein for a diffraction based overlay target having first and second portions separate from each other, a best contrast for the first portion is obtained at a first substrate z-position, and a best contrast for the second portion is obtained at a second substrate z-position, different from the first substrate z-position, the method comprising;
rotating an objective lens element of the metrology apparatus until a best contrast for the first and second portions is achieved at a single substrate z-position, different from the first and second substrate z-positions.

2. A method as in clause 1, wherein the method further comprises performing the rotation over a plurality of intervals and after each interval, measuring a z-position for best contrast for each of the first and second portions.

3. A method as in clause 1, wherein the first and second portions of the overlay target are configured and arranged for use in a non-specular mode of operation of the metrology device.

4. A method as in clause 1, wherein the method further comprises repeating the rotating to change the z-position at which best contrast is achieved based on changes to a fingerprint of an imaging process of the metrology apparatus over time.

5. A method of reducing an effect of linear coma in a metrology apparatus, the method comprising:
determining an amount of an axially symmetric coma aberration present in a lens system of the metrology device; and
moving an optical element of the lens system in an axial z-direction to reduce the determined axially symmetric coma.

6. A method as in clause 5, wherein the moving the optical element comprises moving an aperture stop in the z-direction.

7. A method as in clause 5, wherein the moving the optical element comprises moving a lens element in the z-direction to change a z-position of a pupil of the lens system.

8. A metrology apparatus configured to reduce an effect of coma comprising:
an imaging lens system, configured and arranged to image microscopic diffractive patterns on a substrate;
at least one actuator, disposed within the imaging lens system, and configured and arranged to move at least one optical element of the imaging lens system to reduce the effect of offset and/or linear coma in the imaging lens system.

9. A metrology apparatus as in clause 8, wherein the actuator is configured and arranged to rotate the at least one optical element of the imaging lens system to reduce an effect of offset coma.

10. A metrology apparatus as in clause 8, wherein the actuator is configured and arranged to move the at least one optical element of the imaging lens system in an axial z-direction to reduce an effect of linear offset coma.

11. A metrology apparatus as in clause 10, wherein the at least one optical element is selected from the group consisting of: a field stop, and a lens element, wherein the lens element, when moved in the axial z-direction, shifts a pupil of the imaging lens system in the axial z-direction.

Although specific reference may have been made above to the use of embodiments in the context of lithography using radiation, it will be appreciated that an embodiment of the invention may be used in other applications, for example imprint lithography, and where the context allows, is not limited to lithography using radiation. In imprint lithography, a topography in a patterning device defines the pattern created on a substrate. The topography of the patterning device may be pressed into a layer of resist supplied to the substrate whereupon the resist is cured by applying electromagnetic radiation, heat, pressure or a combination thereof. The patterning device is moved out of the resist leaving a pattern in it after the resist is cured.

Further, although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, liquid-crystal displays (LCDs), thin film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

The patterning device described herein may be referred to as a lithographic patterning device. Thus, the term “lithographic patterning device” may be interpreted as meaning a patterning device which is suitable for use in a lithographic apparatus.

The terms “radiation” and “beam” used herein encompass all types of electromagnetic radiation, including ultraviolet (UV) radiation (e.g. having a wavelength of or about 365, 355, 248, 193, 157 or 126 nm) and extreme ultra-violet (EUV) radiation (e.g. having a wavelength in the range of 5-20 nm), as well as particle beams, such as ion beams or electron beams.

The term “lens”, where the context allows, may refer to any one or combination of various types of optical components, including refractive, reflective, magnetic, electromagnetic and electrostatic optical components.

The embodiment(s) described, and references in the specification to an “embodiment”, “example,” etc., indicate that the embodiment(s) described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

The descriptions above are intended to be illustrative, not limiting. Thus, it will be apparent to one skilled in the art that modifications may be made to the invention as described without departing from the scope of the claims set out below. For example, one or more aspects of one or more embodiments may be combined with or substituted for one or more aspects of one or more other embodiments as appropriate. Therefore, such adaptations and modifications are intended to be within the meaning and range of equivalents of the disclosed embodiments, based on the teaching and guidance presented herein. It is to be understood that the phraseology or terminology herein is for the purpose of description by example, and not of limitation, such that the terminology or phraseology of the present specification is to be interpreted by the skilled artisan in light of the teachings and guidance. The breadth and scope of the invention should not be limited by any of the above-described exemplary embodiments, but should be defined only in accordance with the following claims and their equivalents.

1. A method of reducing an effect of offset coma in a metrology apparatus wherein for a diffraction based overlay target having first and second portions separate from each other, a best contrast for the first portion is obtained at a first substrate z-position, and a best contrast for the second portion is obtained at a second substrate z-position, different from the first substrate z-position, the method comprising;
rotating an objective lens element of the metrology apparatus until a best contrast for the first and second portions is achieved at a single substrate z-position, different from the first and second substrate z-positions.

2. The method as in claim 1, further comprising performing the rotation over a plurality of intervals and after each interval, measuring a z-position for best contrast for each of the first and second portions.

3. The method as in claim 1, wherein the first and second portions of the overlay target are configured and arranged for use in a non-specular mode of operation of the metrology device.

4. The method as in claim 1, further comprising repeating the rotating to change the z-position at which best contrast is achieved based on changes to a fingerprint of an imaging process of the metrology apparatus over time.

5. A method of reducing an effect of linear coma in a metrology apparatus, the method comprising:
determining an amount of an axially symmetric coma aberration present in a lens system of the metrology device; and
moving an optical element of the lens system in an axial z-direction to reduce the determined axially symmetric coma.

6. The method as in claim 5, wherein the moving the optical element comprises moving an aperture stop in the z-direction.

7. The method as in claim 5, wherein the moving the optical element comprises moving a lens element in the z-direction to change a z-position of a pupil of the lens system.

8. A metrology apparatus configured to reduce an effect of coma, the metrology apparatus comprising:
an imaging lens system, configured and arranged to image microscopic diffractive patterns on a substrate; and
at least one actuator, disposed within the imaging lens system, and configured and arranged to move at least one optical element of the imaging lens system to reduce an effect of offset coma and/or linear coma in the imaging lens system.

9. The metrology apparatus as in claim 8, wherein the actuator is configured and arranged to rotate the at least one optical element of the imaging lens system to reduce an effect of offset coma.

10. The metrology apparatus as in claim 8, wherein the actuator is configured and arranged to move the at least one optical element of the imaging lens system in an axial z-direction to reduce an effect of linear coma.

11. The metrology apparatus as in claim 10, wherein the at least one optical element is a field stop, and/or a lens element that, when moved in the axial z-direction, shifts a pupil of the imaging lens system in the axial z-direction.

12. The metrology apparatus as in claim 8, wherein at least one actuator comprises a first actuator configured to move the at least one optical element over a first distance and a second actuator configured to move the at least one optical element over a second distance shorter than the first distance.

13. The metrology apparatus as in claim 8, wherein the second actuator has a higher precision than the first actuator.

14. The method as in claim 1, further comprising measuring the substrate using the rotated objective lens element of the metrology apparatus.

15. The method as in claim 1, further comprising moving an optical element of metrology apparatus in an axial z-direction to reduce linear coma.

16. The method as in claim 5, further comprising measuring the substrate using the rotated objective lens element of the metrology apparatus.

17. The method as in claim 5, further comprising repeating the moving to change the z-position based on changes to a fingerprint of an imaging process of the metrology apparatus over time.

18. The method as in claim 5, further comprising rotating an optical element of the lens system to reduce offset coma.

19. A non-transitory computer-readable medium comprising stored instructions, the instructions, when executed by one or more processors, configured to cause the one or more processors to cause performance of at the least the method of claim 1.

20. A non-transitory computer-readable medium comprising stored instructions, the instructions, when executed by one or more processors, configured to cause the one or more processors to cause performance of at the least the method of claim 5.
